(19) United States
(12) Patent Application Publication
(10) Pub. No.: US 2025/0054844 A1
(43) Pub. Date: Feb. 13, 2025

(54) LEAD FRAME ADAPTED TO BE APPLIED TO A QUAD FLAT NO-LEAD PACKAGE STRUCTURE AND SEMICONDUCTOR DEVICE THEREOF

(71) Applicant: REALTEK SEMICONDUCTOR CORP., Hsinchu (TW)

(72) Inventor: Yu-Hsin Wang, Hsinchu (TW)

(73) Assignee: REALTEK SEMICONDUCTOR CORP., Hsinchu (TW)

(21) Appl. No.: 18/670,938

(22) Filed: May 22, 2024

(30) Foreign Application Priority Data
Aug. 11, 2023 (TW) 112130384

(51) Int. Cl. H01L 23/495; H01L 23/00; H01L 25/065

(52) U.S. Cl. CPC H01L 23/49575; H01L 23/4951; H01L 23/49551; H01L 24/08; H01L 24/48; H01L 25/0657; H01L 2224/08145; H01L 2224/08245; H01L 2224/48138; H01L 2224/48177; H01L 2225/0651; H01L 2225/06527; H01L 2924/0665; H01L 2924/182; H01L 2924/3011

(57) ABSTRACT

A lead frame adapted to be applied to a QFN package structure is provided. The lead frame includes a die-bonding region and a plurality of leads. The die-bonding region is configured to allow a die to be disposed. The leads include a first lead and a plurality of second leads. The first lead includes a first edge pin, an internal pin, and a first extension part. The internal pin is connected to a bottom surface of one of two ends of the first extension part. The first edge pin is connected to a bottom surface of the other end of the first extension part. Each of the second leads includes a second edge pin and a second extension part. The second edge pin is connected to a bottom surface of one of two ends of the second extension part.

### CROSS-REFERENCE TO RELATED APPLICATION

This non-provisional application claims priority under 35 U.S.C. § 119 (a) to patent application No. 112130384 filed in Taiwan, R.O.C. on Aug. 11, 2023, the entire contents of which are hereby incorporated by reference.

### BACKGROUND

### Technical Field

The instant disclosure relates to the design of a lead frame which enhances power integrity, and in particular relates to a lead frame adapted to be applied to a quad flat no-lead (QFN) package structure and a semiconductor device thereof.

### Related Art

A lead frame of the quad flat no-lead (QFN) package known to the inventor provides a low-cost advantage compared to the substrate of the BGA package or the flip chip package. Moreover, when the die is bonded to the lead frame provided with an exposed metal pad, the heat can be dissipated directly through the large area of the exposed metal pad. Therefore, the heat dissipation effect of the QFN package is also better than that of other packaging methods.

However, the QFN package known to the inventor is a wire-bonded lead frame package, and the signal integrity and power integrity of the QFN packages are limited due to the impedance of the wire and internal leads. The longer the wire length is, the greater the impedance is. Therefore, in high-speed signal applications with high signal integrity and power integrity requirements, the QFN packages often have design difficulties due to excessive wire length. As a result, currently, most chip packages containing high-speed signals known to the inventor are still ball grid array (BGA) packages or flip chip packages which are considered to have better signal integrity and power integrity.

### SUMMARY

In one or some embodiments, a lead frame adapted to be applied to a quad flat no-lead (QFN) package structure is provided. The lead frame comprises a die-bonding region and a plurality of leads, wherein the die-bonding region is configured to allow a die to be disposed. The plurality of leads is disposed on a periphery of the die-bonding region. The leads comprise at least one first lead and a plurality of second leads. The at least one first lead is disposed on one side of the die-bonding region. The at least one first lead comprises a first edge pin, an internal pin, and a first extension part. The internal pin is connected to a bottom surface of one of two ends of the first extension part. The first edge pin is connected to a bottom surface of the other end of the first extension part. The internal pin is nearer to the die-bonding region with respect to the first edge pin. Each of the second leads comprises a second edge pin and a second extension part. The second edge pin is connected to a bottom surface of one of two ends of the second extension part. The other end of the second extension part is nearer to the die-bonding region with respect to the end of the second extension part to which the second edge pin is connected.

In one or some embodiments, a lead frame adapted to be applied to a QFN package structure is provided. The lead frame comprises a die-bonding region and a plurality of leads, wherein the die-bonding region is configured to allow a die to be disposed. The plurality of leads is disposed on a periphery of the die-bonding region. The leads comprise at least one first lead and a plurality of second leads. The at least one first lead is disposed on one side of the die-bonding region. The at least one first lead comprises a first edge pin, an internal pin, and a first extension part. The internal pin is connected to a bottom surface of one of two ends of the first extension part. The first edge pin is connected to a bottom surface of the other end of the first extension part. The internal pin is nearer to the die-bonding region with respect to the first edge pin. Each of the second leads comprises a second edge pin and a second extension part. The second edge pin is connected to a bottom surface of one of two ends of the second extension part. The other end of the second extension part is nearer to the die-bonding region with respect to the end of the second extension part to which the second edge pin is connected. An upper surface of the end of the first extension part which is connected to the internal pin is configured to be connected to the die through wire-bonding.

In one or some embodiments, a lead frame adapted to be applied to a QFN package structure is provided. The lead frame comprises a die-bonding region and a plurality of leads, wherein the die-bonding region is configured to allow a die to be disposed. The plurality of leads is disposed on a periphery of the die-bonding region. The leads comprise at least one first lead and a plurality of second leads. The at least one first lead is disposed on one side of the die-bonding region. The at least one first lead comprises a first edge pin, an internal pin, and a first extension part. The internal pin is connected to a bottom surface of one of two ends of the first extension part. The first edge pin is connected to a bottom surface of the other end of the first extension part. The internal pin is nearer to the die-bonding region with respect to the first edge pin. Each of the second leads comprises a second edge pin and a second extension part. The second edge pin is connected to a bottom surface of one of two ends of the second extension part. The other end of the second extension part is nearer to the die-bonding region with respect to the end of the second extension part to which the second edge pin is connected. An upper surface of the end of the first extension part which is connected to the internal pin is configured to be connected to the die through wire-bonding. The at least one first lead is configured to transmit a power signal.

In one or some embodiments, a semiconductor device comprises a die, a lead frame, and a package. The lead frame is adapted to be applied to a QFN package structure. The lead frame comprises a die-bonding region and a plurality of leads, wherein the die-bonding region is configured to allow a die to be disposed. The plurality of leads is disposed on a periphery of the die-bonding region. The leads comprise at least one first lead and a plurality of second leads. The at least one first lead is disposed on one side of the die-bonding region. The at least one first lead comprises a first edge pin, an internal pin, and a first extension part. The internal pin is connected to a bottom surface of one of two ends of the first extension part. The first edge pin is connected to a bottom surface of the other end of the first extension part. The internal pin is nearer to the die-bonding region with respect to the first edge pin. Each of the second leads comprises a second edge pin and a second extension part. The second edge pin is connected to a bottom surface of one of two ends of the second extension part. The other end of the second extension part is nearer to the die-bonding region with respect to the end of the second extension part to which the second edge pin is connected. The package is configured to enclose the die and a portion of the lead frame.

In one or some embodiments, a semiconductor device comprises a die, a lead frame, and a package. The lead frame is adapted to be applied to a QFN package structure. The lead frame comprises a die-bonding region and a plurality of leads, wherein the die-bonding region is configured to allow a die to be disposed. The plurality of leads is disposed on a periphery of the die-bonding region. The leads comprise at least one first lead and a plurality of second leads. The at least one first lead is disposed on one side of the die-bonding region. The at least one first lead comprises a first edge pin, an internal pin, and a first extension part. The internal pin is connected to a bottom surface of one of two ends of the first extension part. The first edge pin is connected to a bottom surface of the other end of the first extension part. The internal pin is nearer to the die-bonding region with respect to the first edge pin. Each of the second leads comprises a second edge pin and a second extension part. The second edge pin is connected to a bottom surface of one of two ends of the second extension part. The other end of the second extension part is nearer to the die-bonding region with respect to the end of the second extension part to which the second edge pin is connected. The package is configured to enclose the die and part of the lead frame. An upper surface of the end of the first extension part which is connected to the internal pin is configured to be connected to the die through wire-bonding.

In one or some embodiments, a semiconductor device comprises a die, a lead frame, and a package. The lead frame is adapted to be applied to a QFN package structure. The lead frame comprises a die-bonding region and a plurality of leads, wherein the die-bonding region is configured to allow a die to be disposed. The plurality of leads is disposed on the periphery of the die-bonding region. The leads comprise at least one first lead and a plurality of second leads. The at least one first lead is disposed on one side of the die-bonding region. The at least one first lead comprises a first edge pin, an internal pin, and a first extension part. The internal pin is connected to a bottom surface of one of two ends of the first extension part. The first edge pin is connected to a bottom surface of the other end of the first extension part. The internal pin is nearer to the die-bonding region with respect to the first edge pin. Each of the second leads comprises a second edge pin and a second extension part. The second edge pin is connected to a bottom surface of one of two ends of the second extension part. The other end of the second extension part is nearer to the die-bonding region with respect to the end of the second extension part to which the second edge pin is connected. The package is configured to enclose the die and part of the lead frame. An upper surface of the end of the first extension part which is connected to the internal pin is configured to be connected to the die through wire-bonding. The at least one first lead is configured to transmit a power signal.

The following will describe the detailed features and advantages of the instant disclosure in detail in the detailed description. The content of the description is sufficient for any person skilled in the art to comprehend the technical context of the instant disclosure and to implement it accordingly. According to the content, claims and drawings disclosed in the instant specification, any person skilled in the art can readily understand the goals and advantages of the instant disclosure.

### BRIEF DESCRIPTION OF THE DRAWINGS

The instant disclosure will become more fully understood from the detailed description given herein below for illustration only, and thus not limitative of the instant disclosure, wherein:

FIG. 1 illustrates a top view of an embodiment of a lead frame adapted to be applied to a QFN package structure and a die;

FIG. 2 illustrates a top view of another embodiment of the lead frame adapted to be applied to the QFN package structure and the die;

FIG. 3 illustrates a bottom view of another embodiment of the lead frame adapted to be applied to the QFN package structure and the die;

FIG. 4 illustrates a cross-sectional view of the lead frame adapted to be applied to the QFN package structure and the die along the sectional line 4 shown in FIG. 3;

FIG. 5A illustrates a schematic view of an embodiment of a first lead;

FIG. 5B illustrates a schematic view of an embodiment of a second lead;

FIG. 6A illustrates a schematic view of an embodiment of the first lead connected to the die through wire-bonding;

FIG. 6B illustrates a schematic view of an embodiment of the second lead connected to the die through wire-bonding;

FIG. 7A illustrates a schematic view of an embodiment of the second lead connected to a decoupling capacitor through a circuit board;

FIG. 7B illustrates a schematic view of an embodiment of the first lead connected to the decoupling capacitor through the circuit board;

and

FIG. 8 illustrates a top view of an embodiment of a semiconductor device.

### DETAILED DESCRIPTION

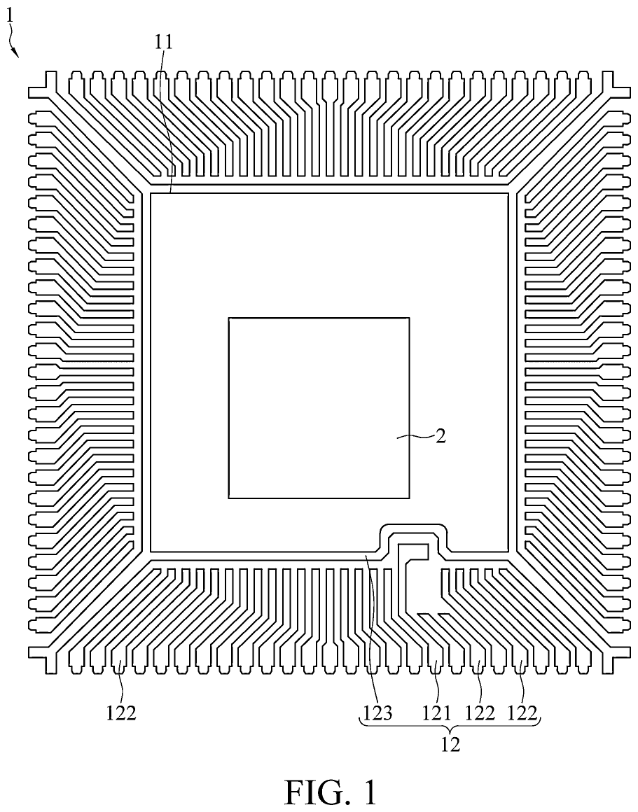

FIG. 1 illustrates a top view of an embodiment of a lead frame 1 adapted to be applied to a QFN package structure and a die 2. Please refer to FIG. 1. A lead frame 1 comprises a die-bonding region 11 and a plurality of leads 12. The die-bonding region 11 is configured to allow a die 2 to be disposed. The plurality of leads 12 is disposed on a periphery of the die-bonding region 11. The leads 12 comprise a first lead 121 and a plurality of second leads 122. For the sake of convenience, only one die 2 is disposed on the die-bonding region 11 as an example, but the instant disclosure is not limited thereto. In some embodiments, the die bonding region 11 is configured to allow a plurality of dies 2 to be disposed, that is, the plurality of dies 2 may be disposed on the die bonding region 11 at the same time. In some embodiments, the die bonding region 11 is configured to allow the die 2 to be adhered and fixed to the die bonding region 11 with epoxy (such as silver epoxy) or die attach film, that is, the die bonding region 11 is configured to allow the die 2 to be adhered and fixed to the die bonding region 11 through the die bonding process.

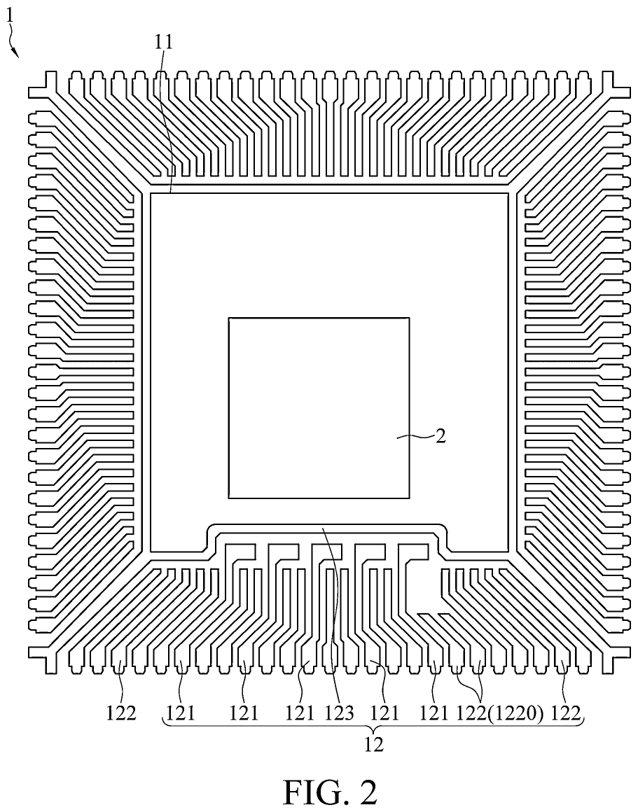

FIG. 2 illustrates a top view of another embodiment of the lead frame 1 adapted to be applied to the QFN package structure and the die 2. Please refer to FIG. 2. In some embodiments, the leads 12 comprise a plurality of first leads 121 and a plurality of second leads 122. The plurality of first leads 121 is disposed on one side of the die-bonding region 11. In the embodiment shown in FIG. 2, the lead frame 1 comprises five first leads 121, but the number of the first leads 121 is not limited thereto.

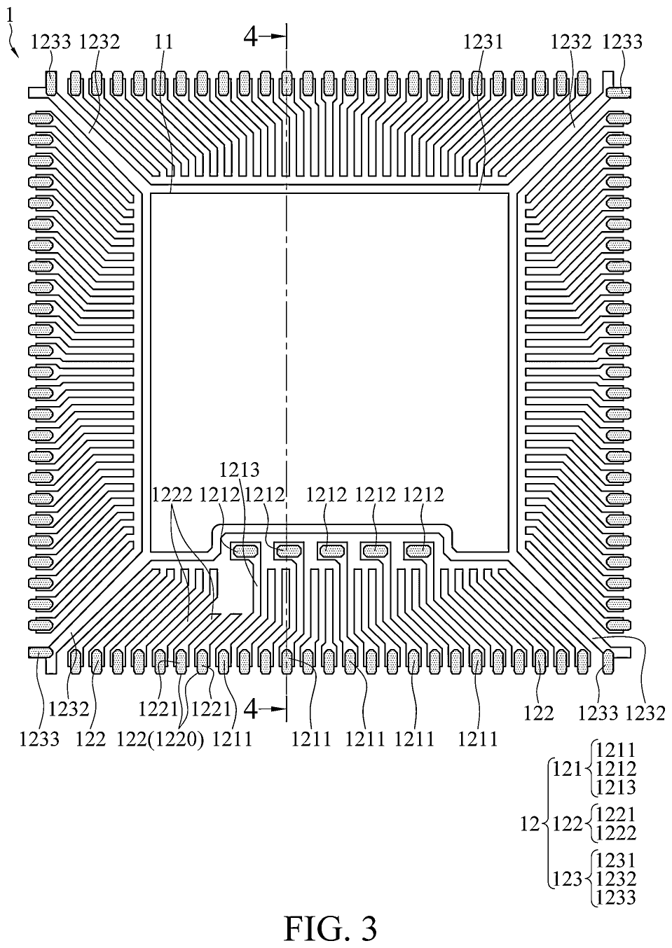

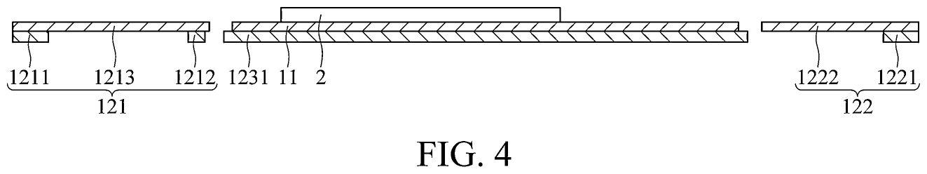

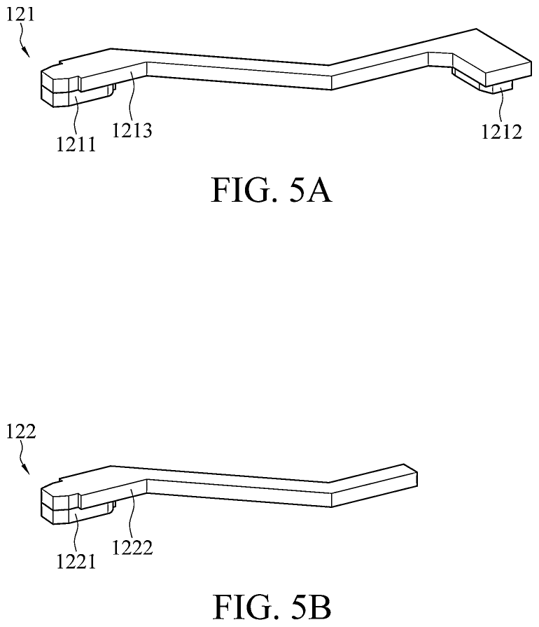

FIG. 3 illustrates a bottom view of another embodiment of the lead frame 1 adapted to be applied to the QFN package structure and the die 2. FIG. 4 illustrates a cross-sectional view of the lead frame 1 adapted to be applied to the QFN package structure and the die 2 along the sectional line 4 shown in FIG. 3. FIG. 5A illustrates a schematic view of an embodiment of the first lead 121. Please refer to FIG. 3 to FIG. 5A. The first lead 121 comprises a first edge pin 1211, an internal pin 1212 and a first extension part 1213. The internal pin 1212 is connected to a bottom surface of one of two ends of the first extension part 1213. The first edge pin 1211 is connected to a bottom surface of the other end of the first extension part 1213. The internal pin 1212 is nearer to the die-bonding region 11 with respect to the first edge pin 1211. That is, for each of the first leads 121, a distance between the internal pin 1212 and the die-bonding region 11 is less than a distance between the first edge pin 1211 and the die-bonding region 11.

FIG. 5B illustrates a schematic view of an embodiment of the second lead 122. Please refer to FIG. 3, FIG. 4 and FIG. 5B. Each of the second leads 122 comprises a second edge pin 1221 and a second extension part 1222. The second edge pin 1221 is connected to a bottom surface of one of two ends of the second extension part 1222. The other end of the second extension part 1222 is nearer to the die-bonding region 11 with respect to the end of the second extension part 1222 to which the second edge pin 1221 is connected.

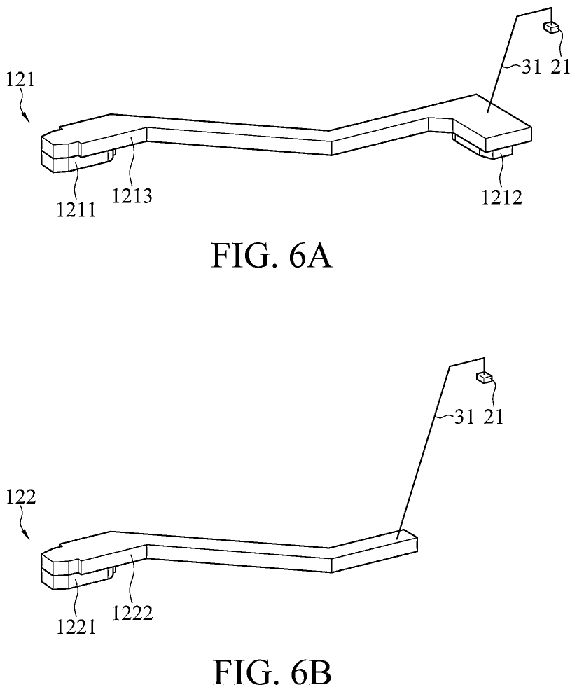

FIG. 6A illustrates a schematic view of an embodiment of the first lead 121 connected to the die 2 through wire-bonding. Please refer to FIG. 6A. An upper surface of the end of the first extension part 1213 which is connected to the internal pin 1212 is wire-bonded to the pad 21 of the die 2 through a wire 31. That is, in some embodiments, the upper surface of the end of the first extension part 1213 which is connected to the internal pin 1212 is soldered to one of two ends of the wire 31, and the other end of the wire 31 is soldered to the pad 21 of the die 2. In some embodiments, the upper surface of the end of the first extension part 1213 which is connected to the internal pin 1212 may also be wire-bonded to a solder pad of the die-bonding region 11 through the wire 31. That is, in some embodiments, the upper surface of the end of the first extension part 1213 which is connected to the internal pin 1212 is soldered to one of two ends of the wire 31, and the other end of the wire 31 is soldered to the solder pad of the die-bonding region 11. In some embodiments, the upper surface of the end of the first extension part 1213 which is connected to the internal pin 1212 may be wire-bonded to the pad 21 of the die 2 or the solder pad of the die-bonding region 11 through one or more wires 31, so that one first lead 121 can transmit one or more identical signals at a time. In some embodiments, the solder pad of the die-bonding region 11 is an exposed metal pad (EPAD).

FIG. 6B illustrates a schematic view of an embodiment of the second lead 122 connected to the die 2 through wire-bonding. Please refer to FIG. 6B. An upper surface of the end of the second extension part 1222 which is not connected to the second edge pin 1221 is wire-bonded to the pad 21 of the die 2 through a wire 31. That is, in some embodiments, the upper surface of the end of the second extension part 1222 which is not connected to the second edge pin 1221 is soldered to one of two ends of the wire 31, and the other end of the wire 31 is soldered to the pad 21 of the die 2. In some embodiments, the upper surface of the end of the second extension part 1222 which is not connected to the second edge pin 1221 may also be wire-bonded to a solder pad of the die-bonding region 11 through the wire 31. That is, in some embodiments, the upper surface of the end of the second extension part 1222 which is not connected to the second edge pin 1221 is soldered to one of two ends of the wire 31, and the other end of the wire 31 is soldered to the solder pad of the die-bonding region 11. In some embodiments, the upper surface of the end of the second extension part 1222 which is not connected to the second edge pin 1221 may be wire-bonded to the pad 21 of the die 2 or the solder pad of the die-bonding region 11 through one or more wires 31, so that one second lead 122 can transmit one or more identical signals at a time.

In some embodiments, the first lead 121 and the second lead 122 are configured to transmit high-speed signals, but the instant disclosure is not limited thereto. The first lead 121 and the second lead 122 may also be configured to transmit low-speed signals. In some embodiments, the first lead 121 is configured to transmit a power signal and the second lead 122 is configured to transmit a differential signal, but the instant disclosure is not limited thereto. The first lead 121 may also be configured to transmit the differential signal or a ground signal and the second lead 122 may also be configured to transmit the power signal or the ground signal.

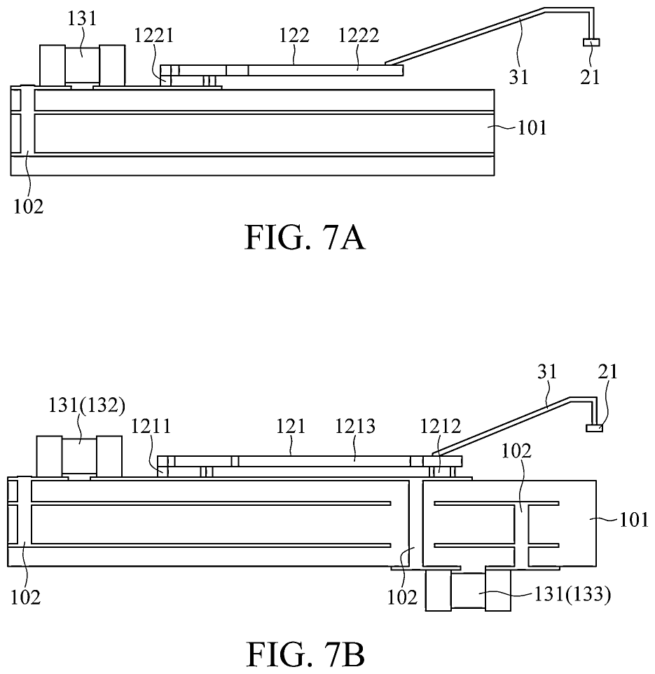

FIG. 7A illustrates a schematic view of an embodiment of the second lead 122 connected to a decoupling capacitor 131 through a circuit board 101. FIG. 7B illustrates a schematic view of an embodiment of the first lead 121 connected to the decoupling capacitor 131 through the circuit board 101. Please refer to FIG. 7A and FIG. 7B. The second lead 122 and the first lead 121 are connected to a decoupling capacitor 131 of a power supply through a trace 102 of a circuit board 101. The trace 102 comprises a fire wire and a ground wire of the power supply. For the sake of convenience, the decoupling capacitors 131 shown in FIG. 7B are referred to as the decoupling capacitor 132 and the decoupling capacitor 133 respectively. It is assumed that the pads 21 in FIG. 7A and FIG. 7B are the same pad 21 of the same die 2. One of the evaluation conditions for the power integrity of the embodiment of FIG. 7A and FIG. 7B is the equivalent inductance value of the path from the pad 21 to the decoupling capacitor 131. The larger the equivalent inductance value is, the greater the voltage jitter on the path from the pad 21 to the decoupling capacitor 131 is. The equivalent inductance value is proportional to the length of the path from the pad 21 to the decoupling capacitor 131. As can be seen from FIG. 7A and FIG. 7B, the length of the path from the pad 21 to the decoupling capacitor 131 in FIG. 7A is apparently greater than the length of the path from the pad 21 to the decoupling capacitor 133 in FIG. 7B. In other words, the equivalent inductance value of the path from the pad 21 to the decoupling capacitor 131 in FIG. 7A is greater than the equivalent inductance value of the path from the pad 21 to the decoupling capacitor 133 in FIG. 7B, that is, the power integrity of the embodiment of FIG. 7B is better than the power integrity of the embodiment of FIG. 7A. Moreover, because the first lead 121 has two pins (the first edge pin 1211 and the internal pin 1212), the embodiment of FIG. 7B has two power paths. If both power paths are used, the power current can also be dispersed, thereby enhancing the power integrity.

From FIG. 3 and FIG. 6A to FIG. 7B, it can be realized that the length of the wire 31 connected between the upper surface of the end of the first extension part 1213 which is connected to the internal pin 1212 and the pad 21 of the die 2 is less than the length of the wire 31 connected between the upper surface of the end of the second extension part 1222 which is not connected to the second edge pin 1221 and the pad 21 of the die 2. Therefore, the wire 31 connected between the upper surface of the end of the first extension part 1213 which is connected to the internal pin 1212 and the pad 21 of the die 2 has smaller impedance than the wire 31 connected between the upper surface of the end of the second extension part 1222 which is not connected to the second edge pin 1221 and the pad 21 of the die 2. On the other hand, the QFN package known to the inventor is the package that uses the lead frame merely containing the plurality of second leads 122 to wire-bond to the die 2. Therefore, according to one or some embodiments of the instant disclosure, the path length from the pad 21 of the die 2 to the power supply can be shortened through the wiring design of the circuit board 101. As a result, according to one or some embodiments of the instant disclosure, the signal transmitted by the first lead 121 in the lead frame 1 has higher signal and power integrity than the QFN package known to the inventor. Consequently, the lead frame 1 can be applied to high-speed signal chip packaging.

Please refer to FIG. 3 and FIG. 4. In some embodiments, the leads 12 further comprise a ground lead 123. The ground lead 123 comprises a ground central pin 1231, a plurality of ground extension parts 1232, and a plurality of ground edge pins 1233. One of two ends of each of the ground extension parts 1232 is connected to a corresponding one of the ground edge pins 1233. The other end of each of the ground extension parts 1232 is connected to the ground central pin 1231. For each of the ground extension parts 1232, the end connected to the ground central pin 1231 is nearer to the die-bonding region with respect to the end to which the ground edge pin 1233 is connected. That is, for each of the ground extension parts 1232, a distance between the end connected to the ground central pin 1231 and the die-bonding region 11 is less than a distance between the end connected to the ground edge pin 1233 and the die-bonding region 11. In some embodiments, the ground central pin 1231 is disposed right below the die-bonding region 11, and an upper surface of the ground central pin 1231 is connected to a bottom surface of the die-bonding region 11. In some embodiments, the ground central pin 1231 may be, but is not limited to, the solder pad of the die bonding region 11.

In some embodiments, each of the ground edge pins 1233 is disposed at a corresponding one of four corners of the die bonding region 11, but the instant disclosure is not limited thereto.

Please refer to FIG. 2 and FIG. 3. In some embodiments, for some of the second leads 122 (i.e., the second lead 1220 shown in FIG. 2 and FIG. 3), due to the difference in length from the first lead 121 or because the first lead 121 compresses the space of the second extension part 1222 of the second lead 122, the second extension part 1222 of the second lead 122 may be slightly retracted.

In some embodiments, the plurality of first leads 121 is disposed on the same side of the die bonding region 11, but the instant disclosure is not limited thereto. The plurality of first leads 121 may also be disposed on multiple sides or symmetrical two sides of the die bonding region 11 at the same time.

In some embodiments, the length of the first edge pin 1211 and the second edge pin 1221 are 400 microns (μm), the length of the second lead 1220 is 1000 μm, the length of the second leads 122 other than the second lead 1220 is 1700 μm, and the length of the first lead 121 is 2160 μm, but the instant disclosure is not limited thereto.

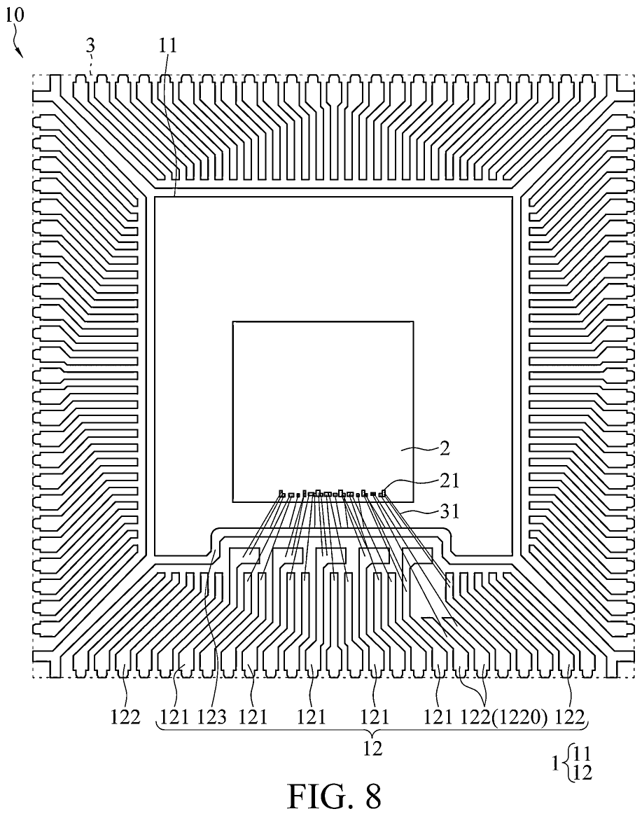

FIG. 8 illustrates a top view of an embodiment of a semiconductor device 10. Please refer to FIG. 8. A semiconductor device 10 comprises a die 2, a lead frame 1, and a package 3, wherein the lead frame 1 is adapted to be applied to a QFN package structure. The lead frame 1 comprises a die-bonding region 11 and a plurality of leads 12. The die-bonding region is configured to allow the die 2 to be disposed. The plurality of first leads 121 is disposed on the same side of the die bonding region 11. The plurality of leads 12 is disposed on a periphery of the die-bonding region 11. The leads 12 comprise a first lead 121 and a plurality of second leads 122. The first lead 121 comprises a first edge pin 1211, an internal pin 1212 and a first extension part 1213. The internal pin 1212 is connected to a bottom surface of one of two ends of the first extension part 1213. The first edge pin 1211 is connected to a bottom surface of the other end of the first extension part 1213. The internal pin 1212 is nearer to the die-bonding region 11 with respect to the first edge pin 1211. That is, for each of the first leads 121, a distance between the internal pin 1212 and the die-bonding region 11 is less than a distance between the first edge pin 1211 and the die-bonding region 11. Each of the second leads 122 comprises a second edge pin 1221 and a second extension part 1222. The second edge pin 1221 is connected to a bottom surface of one of two ends of the second extension part 1222. The other end of the second extension part 1222 is nearer to the die-bonding region 11 with respect to the end of the second extension part 1222 to which the second edge pin 1221 is connected.

In some embodiments, the material of the package 3 may be selected according to the impedance system applied in the semiconductor device 10. In some embodiments, the material of the package 3 may be but not limited to common epoxy resin packaging material or aluminum oxide epoxy resin packaging material.

In some embodiments, the distribution position or number of the plurality of leads 12 in one of the corners of the lead frame 1 may be different from the distribution position or number of the plurality of leads 12 in other corners, so that the user can identify the direction in which the lead frame 1 and the semiconductor device 10 including the lead frame 1 are disposed. In some embodiments, the shape of one of the corners of the die-bonding region 11 may be configured to be different from the shapes of other corners of the die-bonding region 11. For example, one of the corners of the die-bonding region 11 is a missing corner, but the other corners of the die-bonding region 14 are not missing corners, so that the user can identify the direction in which the lead frame 1 and the semiconductor device 10 including the lead frame 1 are disposed by observing the shape of the corners of the die-bonding region 11.

To sum up, in some embodiments, because the wire 31 configured to connect the first lead 121 with the die 2 has smaller impedance, and because the path length from the pad 21 of the die 2 to the power supply can be shortened through the wiring design of the circuit board 101, the signal transmitted by the first lead 121 of the lead frame 1 has higher signal and power integrity than that of the QFN package known to the inventor. Therefore, the lead frame 1 can be applied to high-speed signal chip packaging.

Although the instant disclosure has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A lead frame, adapted to be applied to a quad flat no-lead (QFN) package structure, wherein the lead frame comprises:
a die-bonding region configured to allow a die to be disposed; and
a plurality of leads disposed on a periphery of the die-bonding region, wherein the leads comprise:
at least one first lead disposed on one side of the die-bonding region, wherein the at least one first lead comprises a first edge pin, an internal pin, and a first extension part, the internal pin is connected to a bottom surface of one of two ends of the first extension part, the first edge pin is connected to a bottom surface of the other end of the first extension part, and the internal pin is nearer to the die-bonding region with respect to the first edge pin; and
a plurality of second leads, wherein each of the second leads comprises a second edge pin and a second extension part, the second edge pin is connected to a bottom surface of one of two ends of the second extension part, and the other end of the second extension part is nearer to the die-bonding region with respect to the end of the second extension part to which the second edge pin is connected.

2. The lead frame according to claim 1, wherein an upper surface of the end of the first extension part which is connected to the internal pin is configured to be connected to the die through wire-bonding.

3. The lead frame according to claim 2, wherein the at least one first lead is configured to transmit a power signal.

4. The lead frame according to claim 3, wherein an upper surface of the other end of the second extension part is configured to be connected to the die through wire-bonding.

5. The lead frame according to claim 4, wherein the leads further comprise:
a ground lead, comprising a ground central pin, a plurality of ground extension parts and a plurality of ground edge pins, wherein one of two ends of each of the ground extension parts is connected to a corresponding one of the ground edge pins, the other end of each of the ground extension parts is connected to the ground central pin, and for each of the ground extension parts, the other end is nearer to the die-bonding region with respect to the end to which the ground edge pin is connected.

6. A semiconductor device, comprising:
a die;
a lead frame adapted to be applied to a QFN package structure, wherein the lead frame comprises:
a die-bonding region configured to allow a die to be disposed; and
a plurality of leads disposed on a periphery of the die-bonding region, wherein the leads comprise:
at least one first lead disposed on one side of the die-bonding region, wherein the at least one first lead comprises a first edge pin, an internal pin, and a first extension part, the internal pin is connected to a bottom surface of one of two ends of the first extension part, the first edge pin is connected to a bottom surface of the other end of the first extension part, and the internal pin is nearer to the die-bonding region with respect to the first edge pin; and
a plurality of second leads, wherein each of the second leads comprises a second edge pin and a second extension part, the second edge pin is connected to a bottom surface of one of two ends of the second extension part, and the other end of the second extension part is nearer to the die-bonding region than the end of the second extension part to which the second edge pin is connected; and
a package configured to enclose the die and a portion of the lead frame.

7. The semiconductor device according to claim 6, wherein an upper surface of the end of the first extension part which is connected to the internal pin is configured to be connected to the die through wire-bonding.

8. The semiconductor device according to claim 7, wherein the at least one first lead is configured to transmit a power signal.

9. The semiconductor device according to claim 8, wherein an upper surface of the other end of the second extension part is configured to be connected to the die through wire-bonding.

10. The semiconductor device according to claim 9, wherein the leads further comprise:
a ground lead, comprising a ground central pin, a plurality of ground extension parts and a plurality of ground edge pins, wherein one of two ends of each of the ground extension parts is connected to a corresponding one of the ground edge pins, the other end of each of the ground extension parts is connected to the ground central pin, and for each of the ground extension parts, the other end is nearer to the die-bonding region with respect to the end to which the ground edge pin is connected.
